(19) United States
(12) Patent Application Publication
(10) Pub. No.: US 2005/0058166 A1
(43) Pub. Date: Mar. 17, 2005

(54) Metal waveguides for mode confinement in terahertz lasers and amplifiers

(76) Inventors: Qing Hu, Wellesley, MA (US); Benjamin S. Williams, Cambridge, MA (US)

Correspondence Address: NUTTER MCCLENNEN & FISH LLP, WORLD TRADE CENTER WEST, 155 SEAPORT BOULEVARD, BOSTON, MA, 02210-2604, US

(21) Appl. No.: 10/661,832

(22) Filed: Sep. 12, 2003

(51) Int. Cl. H01S 5/00

(52) U.S. Cl. 372/43; 372/44

(57) ABSTRACT

The present invention provides in one aspect a double-sided metal waveguide that can be utilized in a terahertz laser or amplifier operating in a range of about 1 THz to about 10 THz for mode confinement. For example, the double-sided waveguide can include two metallic layers each of which is disposed on a surface of an active region of a terahertz laser or an amplification region of a terahertz amplifier.

### STATEMENT REGARDING FEDERALLY SPONSORED RESEARCH

This invention was made with government support under Contract No. PO#P927326 awarded by AFOSR, Contract No. NAG5-9080 awarded by NASA, and Contract No. ECS-0217782 awarded by NSF. The government has certain rights in the invention.

### BACKGROUND OF THE INVENTION

The present invention pertains generally to quantum cascade lasers (QCL), and more particularly, it relates to quantum cascade lasers that operate in the terahertz region of the electromagnetic spectrum.

The terahertz region (e.g., ˜1-10 THz, corresponding to a wavelength λ=30-300 μm or a photon energy hω≈4-40 meV) of the electromagnetic spectrum falls between microwave/millimeter and near-infrared/optical frequency ranges. Numerous coherent radiation sources have been developed in the microwave/millimeter and near-infrared/optical frequency ranges. However, despite potential applications of terahertz radiation in a variety of different fields (e.g., spectroscopy in chemistry and biology, plasma diagnostics, remote atmospheric sensing and monitoring, and detection of bio- and chemical agents and explosives for security and military applications), coherent radiation sources operating in the terahertz region remain scarce. The difficulties in developing such radiation sources can be appreciated by considering that semiconductor devices, such as, Gunn oscillators, or Schottky-diode frequency multipliers, that utilize classical real-space charge transport for generating radiation exhibit power levels that decrease as the fourth power of radiation frequency

$$( \frac{1}{{f}^{4}} )$$

as the radiation frequency (f) increases above 1 THz. Further, the radiation frequencies obtained from photonic or quantum electronic devices, such as laser diodes, are limited by the semiconductor energy bandgap of such devices, which is typically higher than 10 THz even for narrow gap lead-salt materials. Thus, the frequency range below 10 THz is not accessible by employing conventional semiconductor laser diodes.

Some unipolar quantum well semiconductor lasers operating in the mid-infrared portion of the electromagnetic spectrum are known. For example, electrically pumped unipolar intersubband transition lasers, commonly known also as quantum cascade lasers, operating at a wavelength of 4 microns were developed at Bell Laboratories in 1994. Since then, major improvements in power levels, operating temperatures, and frequency characteristics have been made for mid-infrared QCLs.

In contrast to such developments of QCL's in the mid-infrared range, the development of terahertz quantum cascade lasers in a frequency range below 10 THz has been considerably more challenging. In particular, small separation of lasing energy levels (about 10 meV), coupled with difficulties associated with mode confinement, at these frequencies contribute to challenges in developing such lasers.

Hence, there is a need for coherent terahertz radiation sources, particularly, coherent sources that generate radiation in a frequency range of about 1 to about 10 THz.

There is also a need for efficient methods for mode confinement in such terahertz lasers.

### SUMMARY OF THE INVENTION

In one aspect, the present invention provides metal waveguides that can be utilized for confining lasing modes of terahertz (THz) lasers that operate in a frequency range of about 1 THz to about 10 THz. A metal waveguide of the invention can be formed of two metallic layers each of which is disposed on a surface of the active region of a quantum cascade laser, which operates at a frequency in a range of about 1 to about 10 THz, so as to confine lasing radiation within the active region.

Such a waveguide of the invention formed of two metallic layers is herein referred to as a double-sided metal waveguide. Each layer can have a single layer structure formed of a selected metallic element or compound, e.g., gold, or alternatively, it can have a multi-layer structure in which each single layer is formed of a different metallic element or compound. For example, one or both of the metallic layers can be formed as a single layer of gold disposed on a single layer of titanium.

Applicants have discovered that utilizing double-sided metal waveguides in terahertz lasers operating in a range of about 1 THz to 10 THz can advantageously allow achieving a mode confinement factor (Γ) that is approximately unity. A mode confinement factor as used herein is defined as the fraction of the radiation beam in the active gain medium. Such a large mode confinement factor can enhance modal gain, and hence facilitate obtaining lasing radiation. In general, in a laser oscillator, the lasing threshold is reached when the modal gain (Γg) equals the total cavity loss (α_{w}+αₘ), where α_{w} is the waveguide loss and αₘ is the facet (mirror) loss. More conveniently, this relation can be expressed as follows:

$$g = \frac{{α}_{w} + {α}_{m}}{Γ} .$$

A double-sided metal waveguide of the invention maximizes the mode confinement factor and hence lowers the threshold gain required for obtaining lasing radiation, thus yielding higher operating temperatures and higher output powers.

Applicants have discovered that the use of double-sided metal waveguides for mode confinement at a frequency range of about 1 to about 10 THz is considerably more advantageous that the use of surface plasmon waveguides, which are employed at higher frequencies. Mode confinement by employing surface plasmons on a semi-insulating substrate degrades with increasing wavelength. In particular, mode penetration into the semi-insulating substrate increases with increasing wavelength. Further, the dielectric constant in the active region decreases with increasing wavelength (e.g., dielectric constant varies as the inverse of the square of operating frequency), thus forcing the radiation mode into the semi-insulating layer that can have a higher dielectric constant. In fact, calculations performed by Applicants indicate that such reduction of the dielectric constant at frequencies below about 2 THz can be so severe such that the radiation mode is no longer confined to the active region.

In a related aspect, each metallic layer of the double-sided waveguide has a thickness that is larger that the skin depth (˜several hundred Å) of the lasing radiation within the active region in that layer. The term “skin depth,” which is known in the art, generally refers to an exponentially decaying spatial extent at which the electric field component of a radiation field that has penetrated into a medium from an interface of that medium with another medium falls to 1/e of its value at the interface. For example, each metallic layer can have a thickness in a range of about 1000 Angstroms to several microns.

In another aspect, the active region of a terahertz laser in which the double-sided metal waveguide is incorporated includes a semiconductor heterostructure that can be formed of a plurality of lasing modules connected in series. Each lasing module includes a plurality of quantum well structures that collectively generate at least an upper lasing state, a lower lasing state, and a relaxation state such that the upper and the lower lasing states are separated by an energy corresponding to an optical frequency in a range of about 1 to about 10 THz. The electrons populating the lower lasing state exhibit a non-radiative relaxation via resonant emission of LO-phonons into the relaxation state.

A double-sided metal waveguide according to the teachings of the invention can be fabricated by utilizing well known techniques. For example, a wafer bonding technique, described in more detail below, can be employed to generate such a double-sided metal waveguide.

In other aspects, a double-sided metal waveguide of the invention can be utilized in a terahertz amplifier for confining radiation to the amplifier's amplification region. Such a terahertz amplifier can include an amplification region for amplifying input signals in a frequency range of about 1 to 10 THz. An incoming signal can be coupled to the amplification region via an input port and an amplified signal can be extracted from the amplifier via an output port. Further, the double-sided metal waveguide can be coupled to the amplification region to ensure that radiation remains confined within this region.

Further understanding of the invention can be obtained by reference to the following detailed description in conjunction with the associated drawings described briefly below.

### BRIEF DESCRIPTION OF THE DRAWINGS

FIG. 1 is a perspective schematic view of a quantum laser according to the teachings of the invention,

FIG. 2 is a cross-sectional view of the laser of FIG. 1 illustrating a heterostructure forming the laser's active region,

FIGS. 3A-3E schematically illustrate various steps in an exemplary fabrication method for generating a double-sided metal waveguide for use in a terahertz laser according to one embodiment of the invention,

FIG. 4A depicts graphs of calculated mode profile and the real part of dielectric constant in various layers of a quantum cascade laser according to one embodiment of the invention at a wavelength of 100 microns and utilizing a waveguide formed of a metal layer and a heavily doped semiconductor layer for mode confinement,

FIG. 4B depicts graphs of calculated mode profile and the real part of dielectric constant in various layers of a quantum cascade laser according to another embodiment of the invention at a wavelength of 100 microns and utilizing a double-sided metal waveguide for mode confinement,

FIG. 5 illustrates an exemplary calculated conduction band profile of two lasing modules of a quantum cascade laser fabricated in accordance with the teachings of the invention,

FIG. 6 is a schematic diagram of an experimental measurement system for testing prototype quantum cascade lasers formed in accordance with the teachings of the invention,

FIG. 7 illustrates a plurality of measured emission spectra of an exemplary quantum cascade laser formed in accordance with the teachings of the invention,

FIG. 8 is a perspective view of a quantum cascade laser according to one embodiment of the invention, which utilizes surface plasmon for mode confinement,

FIG. 9 presents graphs illustrating bias voltage versus injected current, as well as optical power as a function of current, in a proto-type laser formed in accordance with the embodiment of FIG. 8,

FIG. 10 illustrates a plurality of measured emission spectra obtained from a proto-type laser formed in accordance with the embodiment of FIG. 8, and

FIG. 11 is a schematic perspective view of a terahertz amplifier fabricated in accordance with the teachings of the invention.

### DETAILED DESCRIPTION

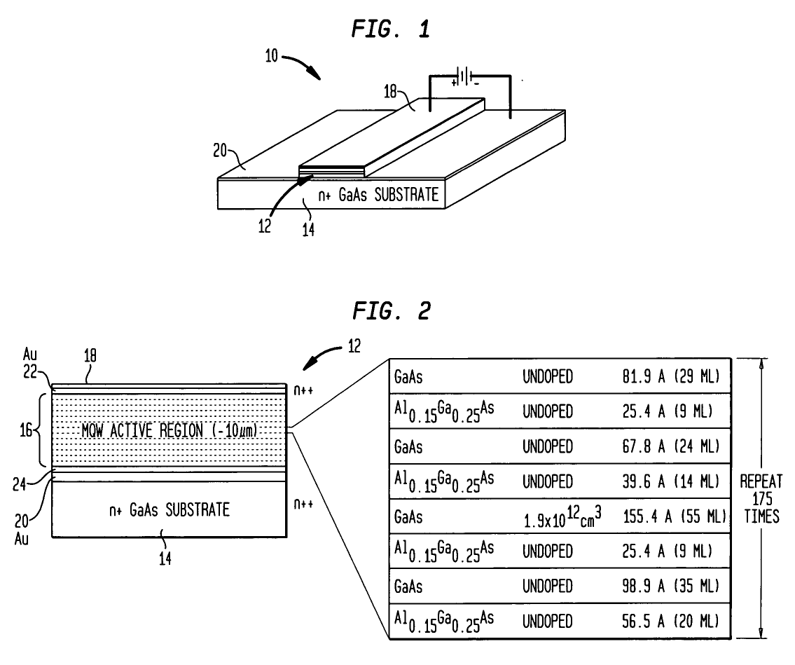

With reference to FIGS. 1 and 2, an exemplary quantum cascade laser 10 according to one exemplary embodiment of the invention includes an active lasing region 12 formed as a heterostructure on a GaAs substrate (for example, an n+ GaAs substrate) 14. The active region 12, which can have a thickness in a range of about 3 microns to about 10 microns (in this exemplary embodiment, the active region has a thickness of about 10 microns), includes a plurality of cascaded nominally identical repeat lasing modules 16, which are coupled in series. The number of the lasing modules can range, for example, from about 100 to about 200. In this exemplary embodiment, the number of lasing modules is selected to be 175.

Each lasing module can be formed as a GaAs/Al_{0.15}Ga_{0.85}As heterostructure. For example, as shown in FIG. 1, in this embodiment, each lasing module, which has an approximate thickness of 600 angstroms, is formed as a stack of alternating Al_{0.15}Ga_{0.85}As and GaAs layers having the illustrated thicknesses. The heterostructure of each lasing module provides four quantum wells that collectively generate lasing and relaxation states, as described in more detail below. More particularly, each GaAs layer sandwiched between two Al_{0.15}Ga_{0.85}As barrier layers functions as a two-dimensional quantum well.

The term “quantum well” is known in the art. To the extent that a definition may be needed, a “quantum well,” as used herein, refers to a generally planar semiconductor region, having a selected composition, that is sandwiched between semiconductor regions (typically referred to as barrier layers) having a different composition, commonly selected to exhibit a larger bandgap energy than that of the composition of the quantum well layer. The spacing between the barrier layers, and consequently the thickness of the quantum well layer, are selected such that charge carriers (e.g., electrons) residing in the quantum well layer exhibit quantum effects in a direction perpendicular to the layer (e.g., they can be characterized by discrete quantized energy states).

Two parallel metallic layers 18 and 20, formed of gold in this embodiment, provide a double sided metal waveguide for confining the lasing modes of the laser 10. The double-sided metal waveguide tightly confines the radiation field, thus yielding a confinement factor close to unity, as discussed in more detail below. Further, as shown in FIG. 1, the upper and lower metallic layers 18 and 20 can be utilized to apply a selected bias voltage across the active region to cause shifting of the energy levels, and injection of electrons into the active region, as discussed in more detail below.

Two heavily doped GaAs upper and lower contact layers 22 and 24 are employed to provide low-resistive contact between the metal layers and the semiconductor active region. In this exemplary embodiment, the upper contact layer 22, which has a thickness of about 60 nm has a doping level of about n=5×10¹⁸ cm⁻³, and the lower contact layer 24, which has a thickness of about 100 nm, has a doping level of about n=3×10¹⁸ cm⁻³. Those having ordinary skill in the art will appreciate that other doping levels can also be utilized.

The operation of a terahertz quantum cascade laser of the invention, such as the above exemplary laser 10, will be discussed in more detail below. However, briefly, in operation, electrons injected into the active region populate an upper lasing state of a lasing module, and generate lasing radiation via optical transitions to a lower lasing state of the module. The energy separation of the upper and the lower lasing states corresponds to a frequency in a range of about 1 to about 10 THz (a wavelength range of about 30 to 300 microns), and hence the lasing radiation has a frequency in this range. The lower lasing state is depopulated via resonant LO-phonon scattering into a relaxation state. The applied bias voltage causes the relaxation state to be in energetic proximity of an upper lasing state of an adjacent lasing module. This allows resonant tunneling of electrons from the relaxation state into the upper lasing state of an adjacent module in a cascading fashion.

The active region 12 can be formed as a heterostructure by employing, for example, molecular beam epitaxy (MBE), chemical vapor deposition (CVD), or any other suitable technique known in the art. A low temperature wafer bonding technique, described in detail below, can be employed to generate the double-sided metal waveguide.

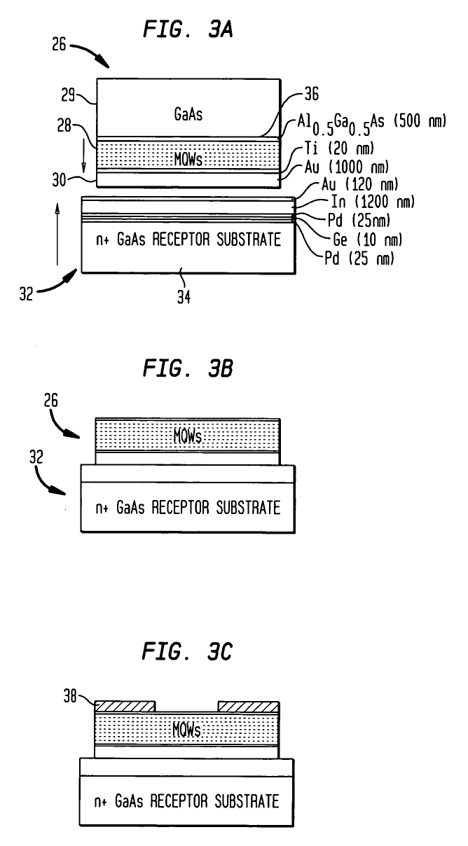

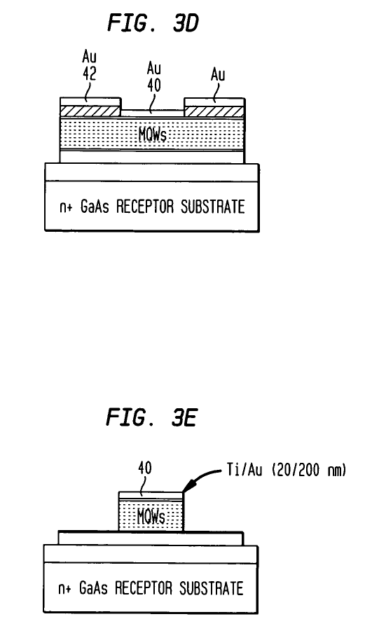

With reference to FIGS. 3A-3E, an exemplary fabrication method for generating the metallic layers 18 and 20 employs a low temperature metal wafer bonding technique followed by substrate removal. More particularly, with reference to FIG. 3A, in an initial step, a wafer 26 containing a multi quantum well (MQW) structure 28 according to the teachings of the invention, formed on a GaAs substrate, is coated with a layer of titanium (Ti) (e.g., a thickness of about 20 nm) and a layer 30 of gold (e.g., a thickness of about 1000 nm). Further, a receptor wafer 32 is prepared by depositing successive layers of palladium (Pd), germanium (Ge), palladium (Pd), indium (In), and gold (Au) on a doped n+ GaAs substrate 34. The Pd/Ge/Pd multi-layer advantageously improves electrical contact to the receptor layer while the topmost gold layer minimizes oxidation of the indium layer.

With reference to FIG. 3B, the two wafers 26 and 32 are bonded together and the GaAs layer 29 is removed. For example, in this exemplary embodiment, wafer pieces having a cross-sectional area of about 1 cm⁻² were cleaved and bonded by maintaining stacked wafers at a temperature of about 250 C on a hot plate for a time duration of about 10 minutes while pressure was applied to the stack. Care was taken to maintain alignment of the crystal axes of the two wafers. Bonding takes place as the indium layer melts, wets the surface to fill in any crevices, and then diffuses into the gold layer to reactively form a variety of In—Au alloys. When the layer thicknesses are properly selected, the indium layer is entirely consumed, and the bonding remains robust up to the eutectic temperature (about 450 C) of the In—Au alloys. The GaAs substrate 29 can be first mechanically lapped and then chemically etched in NH₄OH:H₂O₂ to cause its removal. This selective etch can be stopped at a Al_{0.5}Ga_{0.5}As etch stop layer 36, which can be subsequently removed by employing HF acid.

With reference to FIG. 3C, subsequently, a lithographic mask 38 is applied to the upper surface of the active region by employing known techniques to pattern the surface so as to provide an opening in a central portion of the surface while covering the remainder of the surface. As shown in FIG. 3D, gold is then deposited over the mask to form a gold layer 40 in direct contact with the active region and a gold layer 42 over the lithographic mask. The lithographic mask and the gold layer are then lifted off the surface by dissolving the mask in an appropriate solvent. With reference to FIG. 3E, reactive ion etching, for example, electron cyclotron resonance reactive ion etching in a BCl₃:N₂ gas mixture, can then be utilized to etch the portions of the active region that are not covered by the upper gold layer so as to generate vertical sidewall profiles.

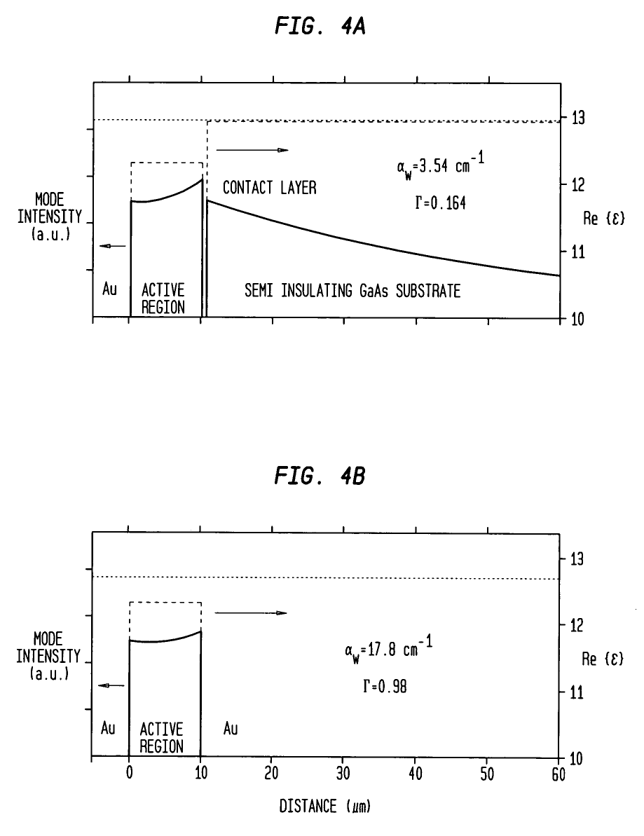

The use of double-sided metal waveguides in quantum cascade lasers operating in a range of about 1 THz to about 10 THz according to the teachings of the invention considerably enhances mode confinement in such lasers, for example, relative to employing semi-insulating surface plasmon waveguides. For example, FIGS. 4A and 4B illustrate calculated mode intensities (solid lines) and the real part of dielectric constants (ε)(dashed lines) at a wavelength of 100 microns in two quantum cascade lasers utilizing, respectively, a waveguide formed of one metallic layer and a semi insulating surface plasmon layer and a double sided metal waveguide. The calculations were based on Drude model for free electrons in various layers. A scattering time of 0.5 picoseconds (ps) was employed for electrons in the lightly doped active region while scattering times of 0.1 ps and 0.05 ps were utilized, respectively, for electrons in a heavily doped n+ GaAs substrate layers and in gold layers.

With continued reference to FIGS. 4A and 4B, the double-sided metal waveguide provides a mode confinement factor close to unity (Γ=0.98), which is considerably larger than the mode confinement factor (Γ=0.164) provided by the surface plasmon waveguide. In particular, while the modal intensity in the laser structure having a surface plasmon waveguide extends considerably into the GaAs substrate (FIG. 4A), the modal intensity in the structure having a double-sided metal waveguide is confined almost completely within the active region. Thus, the structure having a double-sided metal waveguide exhibits a much lower facet loss

$$( \frac{{α}_{m}}{Γ} )$$

than the other structure, although the waveguide losses

$$( \frac{{α}_{w}}{Γ} )$$

exhibited by the two structures are comparable. Hence, utilizing a double-sided metal waveguide at a frequency in a range of about 1 THz to about 10 THz for mode confinement results in a much lower total cavity loss, thus allowing obtaining lasing radiation in structures fabricated based on this mode confinement scheme in the terahertz region of the electromagnetic spectrum.

In addition to providing enhanced mode confinement, a double-sided metal waveguide according to the teachings of the invention can also be employed as a microstrip transmission line that is compatible with integrated circuits. This feature can allow THz QCL devices based on such metal waveguide structures to be readily integrated with other semiconductor devices and circuits.

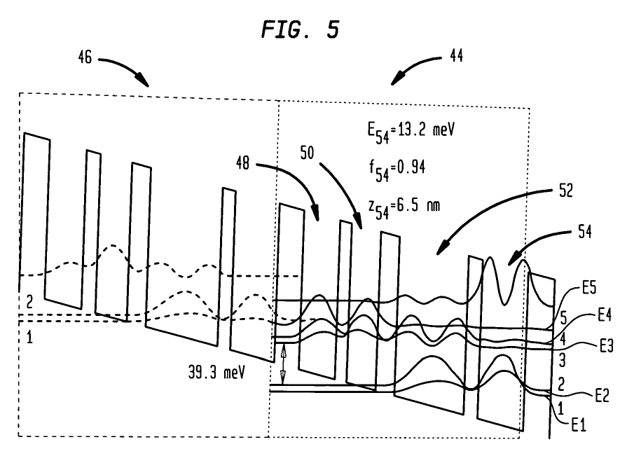

The operation of a quantum cascade laser fabricated in accordance with the teachings of the invention can be better understood by reference to FIG. 5 that schematically illustrates a calculated conduction band profile corresponding to the above exemplary lasing structure 10 of the present exemplary embodiment. Although only two adjacent lasing modules are illustrated in FIG. 5, those having ordinary skill in the art will appreciate that this exemplary illustration is applicable to other modules in the active region. This exemplary conduction band profile depicts the energy levels of two adjacent lasing modules 44 and 46 upon application of a bias voltage of 65 mV/module to the active region. For example, the module 44, which includes four quantum wells 48, 50, 52, and 54, includes quantum states ES, E4, E3, E2, and E1. The adjacent lasing module 46 includes similar energy states, albeit shifted in energy relative to the corresponding states in the module 44 as a result of application of the bias voltage. Each energy state is characterized by a wavefunction whose modulus is indicative of the probability distribution of an electron residing in that state.

The states E5 and E4 form, respectively, an upper lasing state and a lower lasing state of the module 44. In preferred embodiments of the invention, the upper lasing state E5 is separated from the lower lasing state E4 by an energy corresponding to an optical transition frequency in a range of about 1 to about 10 Terahertz (THz) between the two lasing states. For example, in this exemplary embodiment, the energy separation between the upper and the lower lasing states E5 and E4 can be selected to be 13.9 millielectronvolts (meV), which corresponds to an optical transition frequency of 3.38 THz (i.e., a wavelength (λ) of 88.8 microns).

The states E1 and E2 form a relaxation doublet into which electrons residing in the lasing states can transition, primarily via phonon-assisted non-radiative processes. As described in more detail below, the transition rate of electrons from the lower lasing state into the relaxation states is substantially faster than a corresponding transition rate from the upper lasing state into the relaxation state. This difference in transition rates advantageously facilitates generation of a population inversion between the two lasing states. More particularly, at the design bias voltage, the state E3 is brought into resonance with the lower lasing state E4 with a small anticrossing gap, for example, a gap of about 5 meV for a bias voltage of 64 meV in this exemplary embodiment. The state E3 exhibits a fast relaxation rate via resonant LO-phonon scattering into the relaxation double E1/E2. This allows fast resonant LO-phonon scattering from the lower lasing state E4 into the relaxation states to selectively depopulate the lower lasing state, thereby facilitating generation of a population inversion between the lasing states.

A calculation of LO-phonon scattering rates for the exemplary lasing structure 10, performed by employing bulk GaAs phonon modes (a good approximation for structures with low aluminum content), indicates a phonon scattering rate of about 1.8×10¹² s⁻¹(corresponding to a scattering time of ˜0.55 ps) from the lower lasing state into the relaxation doublet (a lifetime of the lower lasing state into the relaxation doublet being τ₄(2,1)=0.55 ps). Further, assuming a fully coherent tunneling process between levels E3 and E4, electron-electron scattering from the lower lasing state E4 into the state E3, which has a short lifetime (e.g., about 0.46 ps for transitions into the relaxation doublet), can cause further depopulation of the lower lasing state.

In contrast, the non-radiative relaxation of the upper lasing state E5 into the states E4 and E3 is suppressed at low temperatures as emission of LO-phonons that can cause such transitions is energetically forbidden (i.e., the energy separation of E5 and E4 can be less than phonon energy). Further, as described in more detail below, the wavefunction of the the upper lasing state and and those of the relaxation states are designed to exhibit poor coupling with one another, thus minimizing non-radiative transitions from the upper lasing state into the relaxation state. Hence, the lifetime of the upper lasing state is substantially longer than that the lifetime of the lower lasing state. For example, in this exemplary embodiment, the lifetime of the lower lasing state τ₄ is about 0.5 ps whereas the lifetime of the upper lasing state τ₅ is about 7 ps. It should be understood that the above calculated numerical values are presented only for further elucidation of salient features of the invention, and are not intended to provide actual values of relaxation rates in all quantum cascade lasers fabricated in accordance with the teachings of the invention.

As is known in the art, the rate of a radiative transition between the lasing states, and the rates of non-radiative transitions between each of the lasing states and the relaxation states are determined, in part, by the shapes of the wavefunctions of these states. In other words, the spatial probability of electron distribution in these states play a role in establishing these transition rates. The selective depopulation of the lower lasing state via resonant LO-phonon scattering can be perhaps better understood by noting that in quantum cascade lasers of the invention, the wavefunctions of the lasing states and the relaxation state (or states) are designed such that the lower lasing state has a substantial coupling to that of the relaxation state while the corresponding coupling between the upper lasing state and the relaxation state is minimized. Moreover, the energy separation of the lower lasing state and the relaxation state (or states) is designed to allow resonant LO-phonon scattering from the lower lasing state into the relaxation state. In addition, the wavefunctions of the two lasing states are designed to exhibit a sufficiently strong coupling that allows efficient radiative transition between these two states.

For example, in this exemplary embodiment, the wavefunction of the upper lasing state E5 has a substantial amplitude in the quantum wells 48 and 50 while exhibiting a substantially diminished amplitude in the quantum wells 52 and 54. In contrast, the wavefunction of the lower lasing state E4 exhibits robust amplitudes in the quantum wells 48 and 50, as well as in quantum well 52, but it has a much lower, amplitude in the quantum well 54. The relaxation states E1 and E2 exhibit very low amplitudes in the quantum wells 48 and 50, but have substantial amplitudes in the quantum wells 52 and 54. Further, the quantum state E3 has a substantial amplitude in the quantum well 52, and a somewhat lower amplitude in the quantum well 48. A coupling between two wavefunctions as used herein, is a measure of an spatial extent over which both wavefunctions have non-vanishing (or substantial) amplitudes. For example, a coupling between two wavefunctions can be obtained by integrating a product of the two wavefunctions over a selected spatial extent. Alternatively, a coupling between two wavefunctions can be obtained by calculating the expectation value of an operator (e.g., dipole moment operator) between the two wavefunctions. A review of the above wavefunctions reveals that the coupling between the wavefunction of the lower lasing state and those of the relaxation states is much more enhanced relative to a similar coupling between the wavefunction of the upper lasing state and those of the relaxation states. More specifically, the wavefunction of the lower lasing state, and that of the state E3 that is in resonance with the lower lasing state, and those of the relaxation states have substantial amplitudes in the quantum well 52, whereas the wavefunction of the upper lasing state has approximately vanishing values in the quantum wells 52 and 54 in which the wavefunctions of the relaxation states peak. Hence, the rate of non-radiative transitions from the lower lasing state into the relaxation state is much higher (e.g., about 10 times larger) than a corresponding rate associated with the upper lasing state.

Further, there exists a good coupling between the wavefunctions of the upper and the lower lasing states because both wavefunctions exhibit substantial amplitudes in the quantum wells 48 and 50. In other words, a radiative transition between the lasing states E5 and E4 is spatially vertical, i.e., it involves electronic transitions within the same quantum well rather than between adjacent quantum wells, thus yielding a large oscillator strength f₅₄, e.g., an oscillator strength of about 0.96 in this embodiment. A large oscillator strength advantageously allows efficient lasing between these two states.

With continued reference to FIG. 5, the relaxation states E1′ and E2′ of the adjacent lasing module 46 are shifted in energy relative to the corresponding relaxation states of the lasing module 44, as a result of application of the bias voltage, so as to be in energetic proximity of the upper lasing state E5. The small energy separation between the states El′ and E2′ and the upper lasing state ES allows transfer of electrons, via resonant tunneling, from the states E1′ and E2′ into the upper lasing state E5, thereby providing a mechanism for populating the upper lasing state E5.

During operation of the laser, electrons are injected into the lasing structure 10, and are transferred from the relaxation state(s) of one lasing module to the upper lasing state of an adjacent lasing module in a cascading fashion. The transfer of electrons into the upper lasing state, coupled with selective depopulation of the lower lasing state via resonant LO-phonon relaxation, generates a population inversion between the upper and the lower lasing states, as described above. The direct use of LO-phonons in quantum cascade lasers of the invention for depopulation of the lower lasing state offers at least two distinct advantages. First, when a relaxation state (collector state) is separated from the lower lasing state by at least E_{LO} (longitudinal optical (LO) phonon energy), depopulation can be extremely fast, and it does not depend much on temperature or electron distribution. Second, the large energy separation between the lower lasing state and the relaxation state inhibits thermal backfilling of the lower lasing state. These properties advantageously allow generating lasers in the terahertz region that operate at relatively high temperatures. For example, as described in more detail below, Applicants have observed lasing in proto-type lasers fabricated in accordance with the teachings of the invention up to an operating temperature of about 137 K.

Although the operation of a quantum cascade laser of the invention was described above with reference to five quantum states in each lasing module, it should be understood that a quantum cascade laser of the invention can function with a minimum of three quantum states in each lasing module such that two of the states form an upper lasing state and a lower lasing state, and third state functions as a relaxation state for depopulating the lower lasing state via resonant LO-phonon scattering.

To illustrate the efficacy of the teachings of the invention for generating quantum cascade lasers that operate in a frequency range of about 1 to about 10 THz, a prototype quantum cascade laser, which operates at a frequency of about 3.8 THz (λ≈79 μm) was constructed and tested. Lasing was observed up to an operating temperature of 137 K. This proto-type lasing structure includes an active region formed of 178 cascaded lasing modules, generated over an insulating GaAs substrate by employing molecular beam epitaxy. Further, cladding and contact layers were grown in a manner described. The thickness of the undoped Al_{0.5}Ga_{0.5}As etch-stop layer in this exemplary prototype structure was selected to be 0.3 microns. Further, the lower n⁺ GaAs contact layer has a thickness of 0.8 microns and is doped at 3×10¹⁸ cm⁻³. Moreover, the intra-injector barrier has a thickness of 30 angstroms resulting in an anticrossing gap of 5 meV between the injector (relaxation) states (E1 and E2). A tighter injector doublet provides a more selective injection into the upper lasing state of an adjacent module. A double-sided metal waveguide was employed for mode confinement.

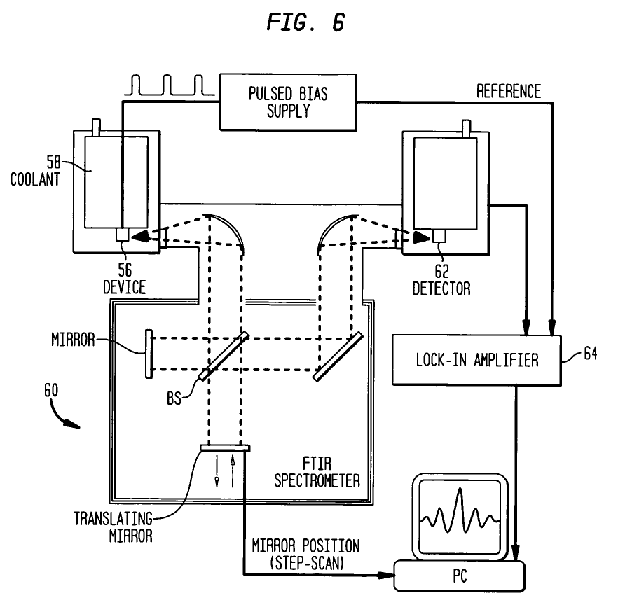

A standard experimental set-up, shown in FIG. 6, was utilized for measurements of the prototype device's lasing emission. A device under test 56 was mounted on a heat sink 58 that was cooled by a coolant to lower the device's temperature to a desired value. A plurality of 200 ns bias pulses were applied to the device to elicit lasing emission therefrom. The lasing emission was coupled to an input of a Fourier transform spectrometer 60 operating at 0.125 cm⁻¹ resolution, and was detected by a Ge:Ga photodetector 62 coupled to an output of the spectrometer. The output of the detector was routed to an input of a lock-in amplifier 64 whose reference input was supplied with the pulse train. The output of the lock-in amplifier provided emission spectra of the device under test.

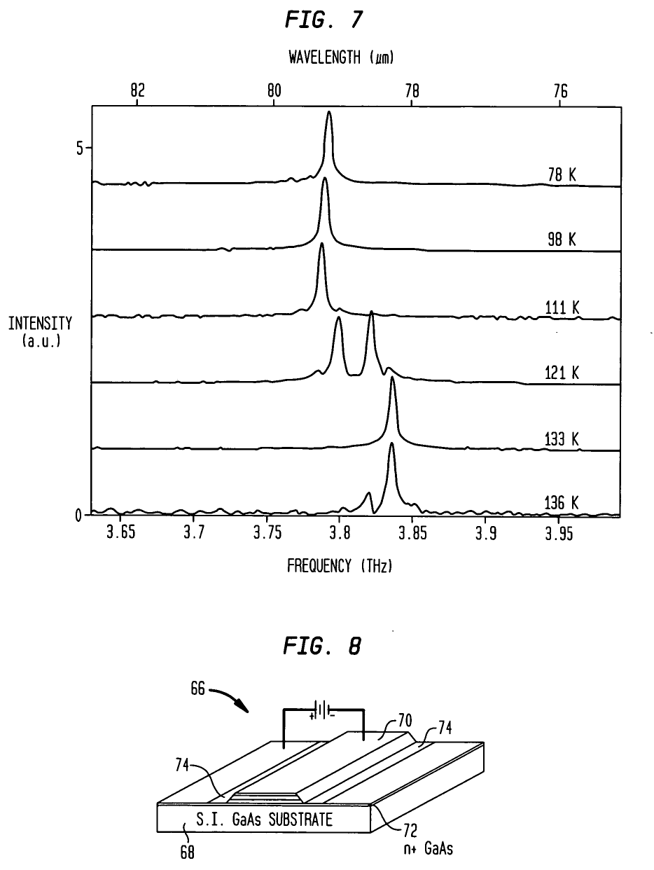

FIG. 7 illustrates observed lasing emission spectra at different temperatures obtained from the above proto-type device. The observed frequency shift at different temperatures is believed to be due to mode-hopping caused by the shift of the gain curve at slightly different bias points, and not to temperature tuning. The spontaneous emission linewidth is measured to be about 6 meV (about 1.5 THz). Without being limited to any theory, this broad linewidth, which is considerably different than a Lorentzian linewidth, is likely due to a non-uniform alignment of different lasing modules.

Although preferred embodiments of the invention employ a double-sided metal waveguide for mode confinement, in some other embodiments of the invention, mode confinement can be achieved by sandwiching an active region between a top metal layer and a heavily doped semiconductor (e.g., GaAs) bottom layer that provides a certain degree of mode confinement via surface plasmon effect. By way of example, FIG. 8 schematically depicts an exemplary quantum cascade laser 66 in accordance with one embodiment of the invention that utilizes surface plasmon for mode confinement. The exemplary laser 66 includes an active region 68 formed as a stack of a plurality of lasing modules, as described above. An upper metallic layer 70 and a heavily doped contact layer 72, for example, a contact layer having a thickness of about 0.8 microns and doped at 3×10¹⁸ cm⁻³ cooperatively provide confinement of the lasing modes. As the plasma frequency associated with this lower contact layer lies above the frequency of interest, a waveguide is formed between the upper metallic contact and the surface plasmons associated with the quasimetallic lower contact layer. More particularly, in this exemplary embodiment, non-alloyed ohmic contacts composed of Ti/Au are deposited on a low temperature grown n++ GaAs top contact layer. Wet etching is then utilized to pattern a few hundred microns wide (e.g., 200 μm) ridges 74. Ni/Ge/Au alloyed contacts can then be made to exposed portions of the contact layer 72 adjacent the ridges to allow, together with the metallic layer 70, application of a bias voltage across the active region.

As described in more detail below, a proto-type device that utilizes a surface plasmon waveguide was fabricated according to the above embodiment of the invention. More particularly, this prototype device included an active region formed as a GaAs/Al_{0.15}Ga_{0.85}As heterostructure fabricated on a 600 micron thick semi-insulating GaAs wafer by employing molecular beam epitaxy. The waveguide and ridges for providing ohmic contact with the lower contact layer were fabricated as described above. A Fabry-Perot cavity was formed by cleaving the structure into a 1.18 mm long bar, and the back facet was coated by evaporating Ti/Au over silicon nitride. The device was then mounted ridge side up on a copper cold finger in a helium cryostat for testing. An measurement system, such as the system shown in above FIG. 6, was then employed to obtain the presented emission data.

The device was tested at a plurality of temperatures in a range of about 5 K to about 87 K. The testing was performed by applying 200 ns long electrical pulses repeated at a rate of 1 kHz (corresponding to a 0.02% duty cycle) to the device. A Ge:Ga photodetector was utilized to measure the intensity of lasing emission. Further, a pyroelectric detector having a 2-mm diameter detecting element onto which an incoming beam can be focused by employing cone optics was utilized to calibrate measurement of absolute power. However, because the collection efficiency was considerably less than unity, the reported uncorrected power levels underestimate the actual emitted power levels. As discussed in more detail below, lasing at a frequency of about 3.4 THz was observed even at a relatively high temperature of 87 K.

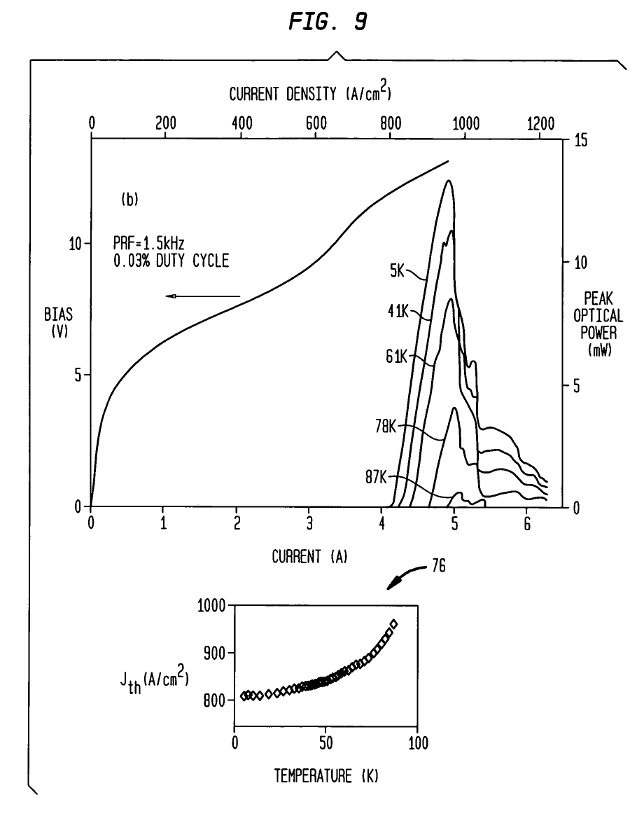

FIG. 9 presents observed laser emission power at a plurality of operating temperatures as a function of applied current in this prototype device, together with bias voltage as a function of current. At a temperature of 5K, a threshold current density (Jₜₕ) of 806 A/cm², and a peak power of ˜14 mW were observed. At an operating temperature of 87 K, Jₜₕ increased to 904 A/cm², and the peak observed power decreased to approximately ˜4 mW. An insert 76 in FIG. 1 illustrates the dependence of the threshold current on operating temperature.

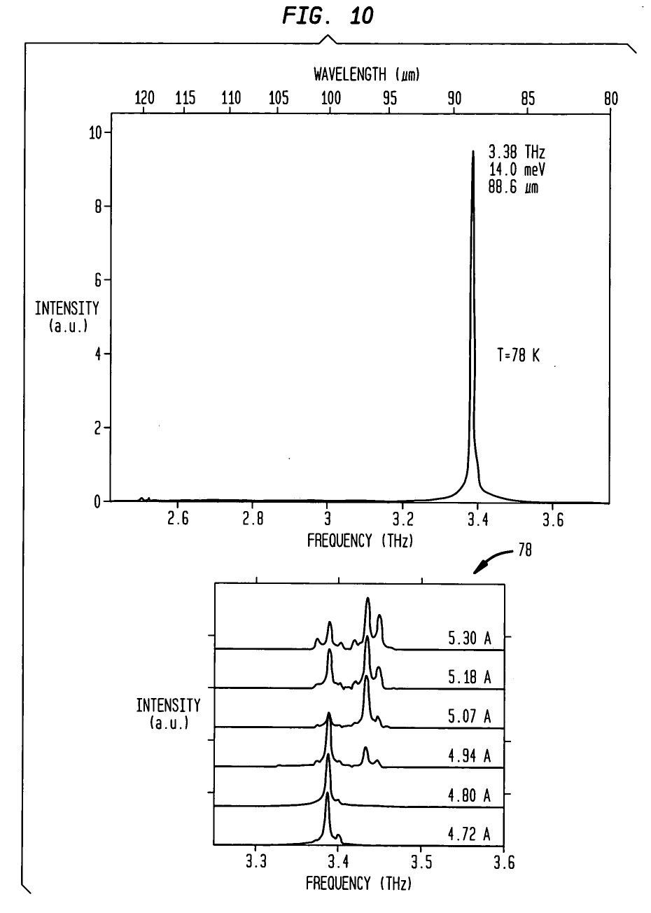

FIG. 10 illustrates a typical lasing emission spectrum of this prototype laser measured at an operating temperature of 78 K. The center frequency of this emission spectrum occurs at a frequency of 3.38 THz corresponding to a wavelength of 88.6 microns (μm). An insert 78 provided in FIG. 10 illustrates a plurality of emission spectra obtained at the same temperature at different values of the injection current density. The observed lasing emission is largely single mode at lower injection currents, for example, in a range in which the slope of power-current relation is positive (i.e., current less than about 4.8A). At high injection currents, e.g., currents above about 4.8 A, the lasing emission power decreases as injection current increases. Without being limited to any particular theory, such decrease of emission power is expected to be due to a misalignment of injector states relative to the corresponding upper lasing states receiving electrons from the injector states. Consequently, the emission spectra at high currents exhibit increasingly multi-mode behavior with shifts to higher frequencies. This blue shift of the frequency is believed to be due to the Stark shift of the intersubband transitions. A measured mode spacing at a temperature of 5 K is approximately 0.51 cm⁻¹, which corresponds to an effective mode index (n_{eff}) of 3.8±0.1. The individual modes are continuously redshifted by approximately 0.16 cm⁻² (i.e., 4.8 GHz) as the operating temperature is increased from about 5 K to about 78 K.

It should be understood that the data presented above in connection with various proto-type lasers fabricated according to the teachings of the invention are provided only for illustrative purposes, and are not intended to necessarily indicate optimal operating characteristics, such as output power or spectral lineshape, of a quantum cascade laser formed according to the teachings of the invention. Moreover, it should be understood that the teachings of the invention can be practiced to generate quantum cascade lasers that operate at frequencies other than those of the above prototype devices, and generally, in a frequency range of about 1 to about 10 THz.

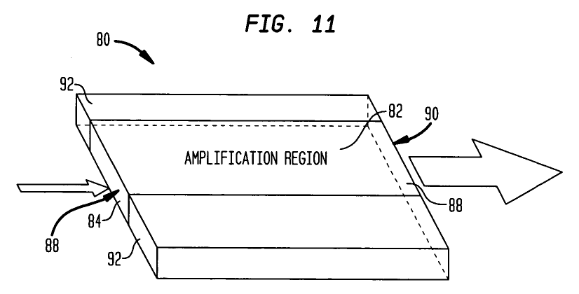

The teachings of invention are not limited to fabricating quantum cascade lasers in a frequency range of about 1 to about 10 THz. In particular, the teachings of the invention can be applied to fabricate amplifiers in this wavelength range. By way of example, FIG. 11 schematically illustrates an amplifier 80 according to one embodiment of the invention that operates in a range of about 1 to about 10 THz. The exemplary amplifier 80 includes an active region 82 formed as a heterostructure, for example, alternating GaAs and Al_{0.15}Ga_{0.85}As layers, in accordance with the teachings of the invention, as described above. Radiation in a frequency range of 1 to 10 THz can be coupled to the active region via an input port 84. Amplified radiation can exit the active region via an output port 86. Input and output facets 88 and 90 are cleaved so as to suppress self oscillation of the amplifying structure due to reflections at these surfaces. Further, a waveguide 92, for example, a double-sided metal waveguide, confines the radiation to the amplification region.

Those having ordinary skill in the art will appreciate that various modifications can be made to the above embodiments without departing from the scope of the invention.

1. A quantum cascade laser, comprising:
an active region for generating lasing radiation in a frequency range of about 1 to about 10 Terahertz, and
a waveguide formed of an upper metallic layer and a lower metallic layer, each layer being disposed on a surface of said active region so as to confine selected modes of said lasing radiation within said active region.

2. The quantum cascade laser for claim 1, wherein said waveguide provides a mode confinement factor of about 1.

3. The quantum cascade laser of claim 1, wherein each of said metallic layers has a thickness in a range of about 0.1 to about several microns

4. The quantum cascade laser of claim 1, wherein at least one of said metallic layers comprises a single layer structure formed of a selected metallic compound.

5. The quantum cascade laser of claim 1, wherein at least one of said metallic layers comprises a multi-layer structure, the layers being formed by at least two different metallic compounds.

6. The quantum cascade laser of claim 4, wherein at least one of said metallic layers comprises a layer of gold.

7. The quantum cascade laser of claim 5, wherein at least one of said metallic layers comprises a layer of gold disposed over a layer of titanium.

8. The quantum cascade laser of claim 1, wherein said active region comprises a semiconductor heterostructure providing a plurality of lasing modules connected in series.

9. The quantum cascade laser of claim 4, wherein each lasing module comprises
a plurality of quantum well structures collectively generating at least an upper lasing state, a lower lasing state, and a relaxation state such that said upper and lower lasing states are separated by an energy corresponding to an optical frequency in a range of about 1 to about 10 Terahertz, and
wherein electrons populating said lower lasing state exhibit a non-radiative relaxation via resonant emission of LO-phonons into said relaxation state.

10. The quantum cascade laser of claim 1, further comprising two contact layers each disposed between a surface of said semiconductor heterostructure and one of said metallic layers.

11. The quantum cascade laser of claim 10, wherein each contact layer comprises a heavily doped semiconductor.

12. The quantum cascade laser of claim 11, wherein said heavily doped semiconductor layer comprises a GaAs layer having a doping level of about 10¹⁸ cm⁻³.

13. The quantum cascade laser of claim 9, wherein said semiconductor heterostructure is formed as alternating layers of GaAs and Al_{0.15}Ga_{0.85}As.

14. The quantum cascade laser of claim 9, wherein a vertical optical transition between said upper lasing state and said lower lasing state generates lasing radiation in a range of about 1 THz to about 10 THz.

15. A method of confining a mode profile of radiation in a quantum cascade laser, comprising:
disposing an active region of said quantum cascade laser between an upper metallic layer and a lower metallic layer,
wherein each metallic layer has a thickness larger than a skin depth of radiation in a frequency range of about 1 THz to about 10 THz in said metallic layer.

16. The method of claim 15, further comprising depositing at least one of said metallic layers on a surface of said active region by employing molecular beam epitaxy.

17. The method of claim 15, further comprising employing a wafer bonding technique to generate said upper and lower metallic layers.

18. A Terahertz amplifier, comprising
an amplification region for amplifying an incoming radiation signal having a frequency in a range of about 1 THz to about 10 THz to generate an amplified signal,
an input port for coupling said incoming radiation into said amplification region,
an exit port for extracting said amplified signal from said amplification region, and
a waveguide formed of an upper and a lower metallic layer diposed on opposing surfaces of said amplification region to confine radiation within said amplification region.
